(19) United States
(12) Patent Application Publication
(10) Pub. No.: US 2024/0094624 A1
(43) Pub. Date: Mar. 21, 2024

(54) PATTERN FORMATION METHOD, SEMICONDUCTOR DEVICE MANUFACTURING METHOD, AND IMPRINT APPARATUS

(71) Applicant: Kioxia Corporation, Tokyo (JP)

(72) Inventors: Masaki MITSUYASU, Kuwana Mie (JP); Ryo OGAWA, Mie Mie (JP); Anupam MITRA, Yokkaichi Mie (JP)

(21) Appl. No.: 18/457,983

(22) Filed: Aug. 29, 2023

(30) Foreign Application Priority Data
Sep. 20, 2022 (JP) 2022-149227

(51) Int. Cl. G03F 1/42; G03F 7/00; G03F 9/00; H01L 21/3213

(52) U.S. Cl. CPC G03F 1/42; G03F 7/0002; G03F 9/7073; H01L 21/32139

(57) ABSTRACT

According to one embodiment, a pattern formation method includes holding a substrate on a suction chuck that an outer suction region for an outer edge portion of the substrate and an inner suction region for an inner region of the substrate. A partial shot region at an outer edge of the substrate has a first alignment mark in the inner region and a second alignment mark at the outer edge portion. While a template is being pressed against a resin film in the shot region, position alignment using the second and fourth alignment marks is performed by adjusting a suction force for the outer suction region for changing a warpage amount of the substrate while observing the second and fourth alignment marks through the template.

### CROSS-REFERENCE TO RELATED APPLICATION(S)

This application is based upon and claims the benefit of priority from Japanese Patent Application No. 2022-149227, filed Sep. 20, 2022, the entire contents of which are incorporated herein by reference.

### FIELD

Embodiments described herein relate generally to a pattern formation method, a semiconductor device manufacturing method, and an imprint apparatus.

### BACKGROUND

An imprint process may be included in a manufacturing of a semiconductor device. In an imprint process, a substrate can be suctioned onto a vacuum chuck, and then a template pressed against a resin film formed on the substrate. A pattern of the template is transferred to the resin film, and then transferred to the substrate or the like.

When the pattern is transferred in the imprint process, alignment marks formed on both the substrate and the template are used to align the transfer position of the pattern with respect to the substrate. However, if the substrate is warped, for example, by being suctioned onto the vacuum chuck, the transfer position of the pattern may be displaced from an intended or ideal position.

### BRIEF DESCRIPTION OF THE DRAWINGS

FIGS. 1A and 1B are schematic diagrams of an imprint apparatus according to an embodiment.

FIGS. 2A and 2B are schematic diagrams of a wafer chuck provided in an imprint apparatus according to an embodiment.

FIG. 3 is schematic diagram illustrating aspects of a template stage provided in an imprint apparatus according to an embodiment.

FIG. 4 illustrated an example of a wafer according to an embodiment.

FIGS. 5A to 5E are cross-sectional diagrams sequentially illustrating a part of a procedure of a method for manufacturing a semiconductor device according to an embodiment.

FIGS. 6A to 6C are cross-sectional diagrams sequentially illustrating another part of the procedure of the method for manufacturing a semiconductor device according to the embodiment.

FIG. 7 illustrates aspects of an alignment operation performed by an imprint apparatus according to an embodiment.

FIGS. 8A and 8B are schematic diagrams illustrating a relationship between a relative position of alignment marks of a template and the wafer and a warpage amount of wafer according to a comparative example.

FIG. 9 illustrates aspects of an alignment operation performed by an imprint apparatus according to a modification example of an embodiment.

FIGS. 10A and 10B are top views illustrating an example of a configuration of moiré-type alignment marks provided on a template and a wafer according to another modification example of an embodiment.

### DETAILED DESCRIPTION

Embodiments provide a pattern formation method, a semiconductor device manufacturing method, and an imprint apparatus capable of improving overlapping (alignment) accuracy of a pattern on a substrate.

In general, according to one embodiment, a pattern formation method includes holding a substrate using a suction chuck. The substrate has a plurality of shot regions thereon. The suction chuck has a first suction region for suctioning an outer edge portion of the substrate and a second suction region for suctioning an inner region of the substrate. A resin film is formed on a shot region of the plurality of shot regions, and a template is pressed against the resin film on the shot region to transfer a pattern of the template to the resin film. The plurality of shot regions include a partial shot region in the outer edge portion and the inner region of the substrate. The partial shot region has a first alignment mark in the inner region and a second alignment mark in the outer edge portion. The template includes a third alignment mark for position alignment with the first alignment mark, and a fourth alignment mark for position alignment with the second alignment mark. The position alignment of the first and third alignment marks is performed with the template being pressed against the resin film in the partial shot region. The position alignment of the second and fourth alignment marks is performed by adjusting a suction force for the first suction region for changing a warpage amount of the outer edge portion while observing the second and fourth alignment marks through the template with the template being pressed against the resin film in the partial shot region.

Hereinafter, certain example embodiments of the present disclosure will be described with reference to the drawings. The present disclosure is not limited to these specific examples.

The present disclosure additionally those modifications obvious to those of ordinary skilled in the art and equivalents.

### Configuration Example of Imprint Apparatus

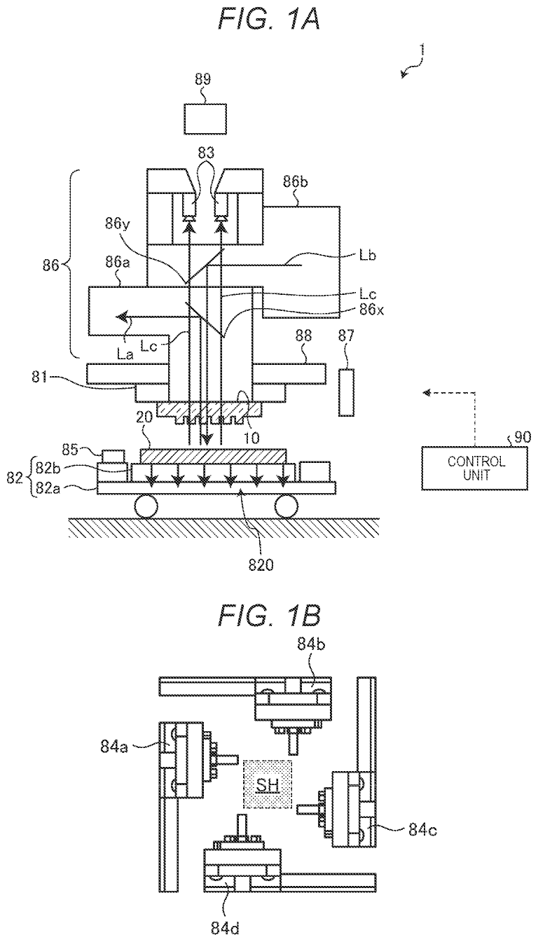

FIGS. 1A and 1B are schematic diagrams illustrating an example of a configuration of an imprint apparatus 1 according to an embodiment. FIG. 1A is an overall view of the imprint apparatus 1, and FIG. 1B is an enlarged view of a detection system 86a illustrating a configuration of an image sensor 84 (imaging sensors 84a to 84d) provided in the imprint apparatus 1.

As illustrated in FIGS. 1A and 1B, the imprint apparatus 1 includes a template stage 81, a wafer stage 82, imaging sensors 83 and 84a to 84d, a reference mark 85, an alignment unit 86, a liquid droplet dropping device 87, a stage base 88, a light source 89, a control unit 90, and a memory unit 91. A template 10 for transferring a pattern to a resist on a wafer 20 is installed in the imprint apparatus 1.

The wafer stage 82 has a wafer chuck 82b and a main body 82a. The wafer chuck 82b has a plurality of suction paths 820 for suctioning a rear surface of the wafer 20, and fixes the wafer 20 at a predetermined position on the main body 82a. The plurality of suction paths 820 are each connected to a pump.

The reference mark 85 is provided on the wafer stage 82. The reference mark 85 can be used for position alignment when loading the wafer 20 onto the wafer stage 82.

The wafer 20 is placed on the wafer stage 82, and the wafer stage 82 is moved in a plane parallel to the placed wafer 20 (in a horizontal plane). The wafer stage 82 moves the wafer 20 to a position underneath the liquid droplet dropping device 87 when dropping a resist onto the wafer 20, and moves the wafer 20 to a position underneath the template 10 when performing a transfer process to the wafer 20.

The stage base 88 supports the template 10 by the template stage 81, and is moved in an up-down direction (vertically) to press the pattern of the template 10 against the resist on the wafer 20.

The alignment unit 86 having a plurality of imaging sensors 83 is provided on the stage base 88. The alignment unit 86 detects a position of the wafer 20 and detects a position of the template 10, based on an alignment mark provided on each of the wafer 20 and the template 10.

The alignment unit 86 includes the detection system 86a and a lighting system 86b. The lighting system 86b emits light onto the wafer 20 and the template 10 to make the alignment marks formed at the wafer 20 and the template 10 visible. The detection system 86a detects images of the alignment marks, and aligns the images for position alignment of the wafer 20 and the template 10.

The detection system 86a and the lighting system 86b are provided with mirrors 86x and 86y such as dichroic mirrors, respectively, as imaging units. The mirrors 86x and 86y form images from the wafer 20 and the template 10, such as the alignment marks, with light from the lighting system 86b.

Specifically, light Lb from the lighting system 86b is reflected downward to a position at which the wafer 20 or the like is disposed, by the mirror 86y. Light La from the wafer 20 or the like is reflected toward the detection system 86a side by the mirror 86x. A part of light Lc from the wafer 20 or the like passes through the mirrors 86x and 86y and travels toward the imaging sensor 83 side above.

The imaging sensor 83 captures this part of the light Lc as an image including the alignment mark or the like. The image captured by the imaging sensor 83 is used by the control unit 90 to determine a state of the alignment mark.

The light La reflected by the mirror 86x toward the detection system 86a side travels toward a side of a plurality of imaging sensors 84a to 84d provided in the detection system 86a.

As illustrated in FIG. 1B, the plurality of imaging sensors 84a to 84d are arranged to be able to respectively image different points of one shot region SH on the wafer 20, which is an imprint region of the template 10, for example.

The imaging sensors 84a to 84d capture the light La reflected by the mirror 86x as an image including the alignment mark or the like. The images captured by the imaging sensors 84a to 84d are used by the control unit 90 for position alignment between the wafer 20 and the template 10.

The liquid droplet dropping device 87 dispenses a resist onto the wafer 20 by an ink jet method. An ink jet head provided in the liquid droplet dropping device 87 has a plurality of fine holes for ejecting resist droplets, and dispenses the resist droplets onto one shot region SH on the wafer 20.

Although the imprint apparatus 1 is configured to dispense a resist onto the wafer 20 in this example, in other examples, the resist may be applied over the entire surface of the wafer 20 by a spin coating method or the like.

The light source 89 is a device for emitting light such as ultraviolet rays for curing the resist and is provided above the stage base 88. The light source 89 emits light from above the template 10 while the template 10 is pressed against the resist.

The control unit 90 can include a hardware processor such as a central processing unit (CPU), a memory, a hard disk drive (HDD), and the like. The control unit 90 controls the template stage 81, the wafer stage 82, the reference mark 85, the alignment unit 86 including the imaging sensors 83 and 84a to 84d, the liquid droplet dropping device 87, the stage base 88, and the light source 89.

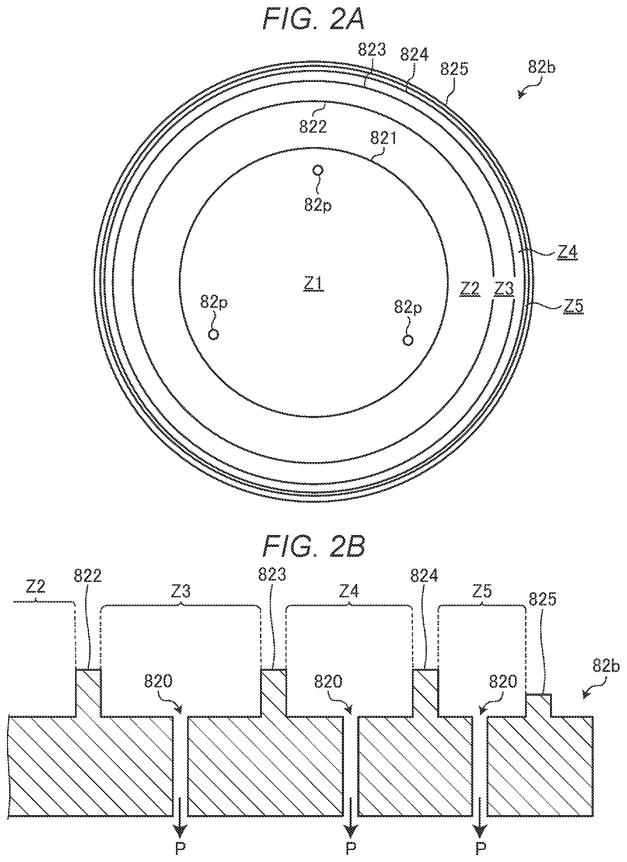

Next, a wafer chuck 82b provided in the imprint apparatus 1 will be described with reference to FIGS. 2A and 2B.

FIGS. 2A and 2B are schematic diagrams illustrating an example of a configuration of the wafer chuck 82b provided in the imprint apparatus 1 according to the embodiment. FIG. 2A is a top view of the wafer chuck 82b, and FIG. 2B is a partially enlarged cross-sectional diagram of the wafer chuck 82b.

As illustrated in FIG. 2A, the wafer chuck 82b as a suction chuck is divided into a plurality of zones Z1 to Z5 by a plurality of ring-shaped projections 821 to 825.

The plurality of ring-shaped projections 821 to 825 are arranged concentrically in this order from an inside to an outside of the wafer chuck 82b. Intervals between these ring-shaped projections 821 to 825 become narrower toward the outside of the wafer chuck 82b.

The zone Z1 is a circular shape region further inside the ring-shaped projection 821 disposed at a center of the wafer chuck 82b. Further, the zone Z1 is provided with a plurality of pin holes 82p. Wafer pins are accommodated in the plurality of pin holes 82p. The wafer pins project from a surface of the wafer chuck 82b to hold the wafer 20 at position above the wafer chuck 82b when the wafer 20 is being loaded and unloaded.

The zone Z2 is an annular region located between the ring-shaped projections 821 and 822. The zone Z3 is an annular region located between the ring-shaped projections 822 and 823. The zone Z4 is an annular region located between the ring-shaped projections 823 and 824. The zone Z5 is an annular region located between the ring-shaped projections 824 and 825.

As illustrated in FIG. 2B, the plurality of ring-shaped projections 821 to 825 project from the surface of wafer chuck 82b. Among the plurality of ring-shaped projections 821 to 825, projection heights of the ring-shaped projections 821 to 824 are equal to each other. The ring-shaped projection 825 disposed at an outermost periphery of the wafer chuck 82b has a lower projection height than the other ring-shaped projections 821 to 824.

The plurality of suction paths 820 connected to pumps P on the downstream side are provided inside the wafer chuck 82b. These suction paths 820 respectively open into the zones Z1 to Z5 divided by the plurality of ring-shaped projections 821 to 825.

The suction path 820 does not open beyond the ring-shaped projection 825 disposed nearest the outermost edge of the wafer chuck 82b, that is, in an annular region up to an outer edge portion of the wafer chuck 82b outside the zone Z5.

The wafer 20 is placed on the wafer stage 82 with the rear (backside) surface of the wafer 20 supported by at least upper end portions of the ring-shaped projections 821 to 824 among the plurality of ring-shaped projections 821 to 825. Thus, an inner region of the wafer 20 is disposed at a position overlapping with the zones Z1 to Z4 of the wafer chuck 82b, and the outer edge portion of the wafer 20 is disposed at a position overlapping with the zone Z5 of the wafer chuck 82b.

In With wafer 20 supported on the upper end portions of the ring-shaped projections 821 to 824, by operating the pumps P connected to the plurality of suction paths 820 and suctioning the rear surface of the wafer 20 from a plurality of openings of the suction paths 820 provided in the respective zones Z1 to Z5, the wafer 20 is held onto the upper surface of the wafer chuck 82b.

At this time, by controlling an operating state of the pump P or the like, it is possible to individually adjust a suction force for each of the zones Z1 to Z5. In addition, it is possible not only to apply suction to the rear surface of the wafer 20 to create a negative pressure, but also to apply a positive pressure to the rear surface of the wafer 20. Further, a valve or the like may be provided in each of the plurality of suction paths 820, and the suction force for each of the zones Z1 to Z5 may be adjusted by opening and closing these valves. Thus, for example, the number of pumps P connected to the suction path 820 can be reduced.

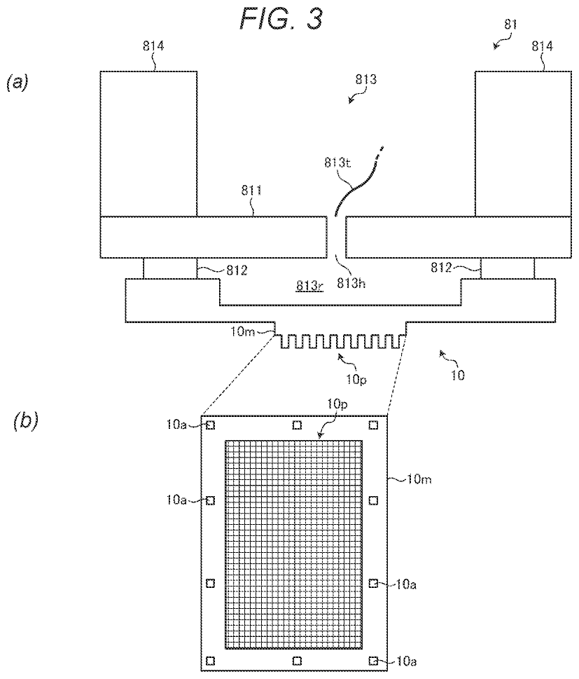

Next, a configuration example of the template stage 81 provided in the imprint apparatus 1 and the template 10 held by the template stage 81 will be described with reference to FIG. 3.

FIG. 3 illustrates an example of a configuration of the template stage 81 provided in the imprint apparatus 1 according to the embodiment. FIG. 3, part (a) is a cross-sectional diagram of the template stage 81, and FIG. 3, part (b) is a top view of a pattern PT provided in the template 10 held by the template stage 81.

As illustrated in FIG. 3, the template stage 81 includes a main body 811, a template chuck 812, a pressing unit 813, and a driving unit 814.

The main body 811 of the template stage 81 is a plate-shaped member, and holds the template 10 on a lower surface of the main body 811 by the template chuck 812. The template chuck 812 is provided on the lower surface of the main body 811, and holds the template 10 above the wafer 20 with the pattern 10p facing downward by vacuum suction provided by a suction mechanism.

The pressing unit 813 includes a pressing chamber 813r which is a space between the main body 811 of the template stage 81 and the template 10, a through-hole 813h provided in the main body 811 and communicating with the pressing chamber 813r, and a tube 813t connected to the through-hole 813h.

The pressing unit 813 can press a rear surface of the template 10 with air pressure or the like by flowing air or the like into the pressing chamber 813r from the tube 813t via the through-hole 813h. When the template 10 is pressed against the resist on the wafer 20, the rear surface of the template 10 is pressed by the pressing unit 813, so that a center portion of the pattern 10p of the template 10 is at a state of being bent toward the wafer 20 side.

The driving unit 814 lifts and lowers the template stage 81 holding the template 10 by a motor or the like. At this time, by adjusting a drive force of the motor or the like of the driving unit 814, it is possible to control a lifting-lowering speed of the template stage 81, an inclination of the template 10 with respect to the wafer 20, a force with which the pattern 10p of the template 10 is pressed against the resist on the wafer 20, and the like.

More specifically, the driving unit 814 can apply a force individually to each of the four corners of the rectangular-shaped template 10, for example. Therefore, the driving unit 814 can adjust the inclination (tilt) of the template 10 by applying different forces to the four corners of the template 10. Further, the driving unit 814 can adjust the force with which the template 10 is pressed against the resist by changing the strength of the force applied to the template 10 at the four corners. The force pressing the template 10 against the resist is also referred to as an imprinting force of the template 10.

In addition, the driving unit 814 moves the template stage 81 in a direction along surfaces of the template 10 and the wafer 20, that is, in a horizontal direction by a motor or the like. Thus, relative positions in the horizontal direction between the template 10 and the wafer 20 are adjusted.

The template 10 is a substantially flat quartz member or the like and includes a mesa portion 10m projecting from a lower surface. A pattern 10p is formed on a surface of the mesa portion 10m. The pattern 10p can be a pattern having any shape or form such as a line-and-space pattern, a dot pattern, a hole pattern, or the like. The pattern 10p is transferred to the resist on the wafer 20. A region on the wafer 20 to which the pattern 10p is transferred becomes an element region of a semiconductor device.

A plurality of alignment marks 10a are provided around the pattern 10p on the template 10. Each alignment mark 10a has, for example, a recess shape recessed from a contact surface with the resist when the template 10 is pressed against the resist on the wafer 20.

### Method for Manufacturing Semiconductor Device

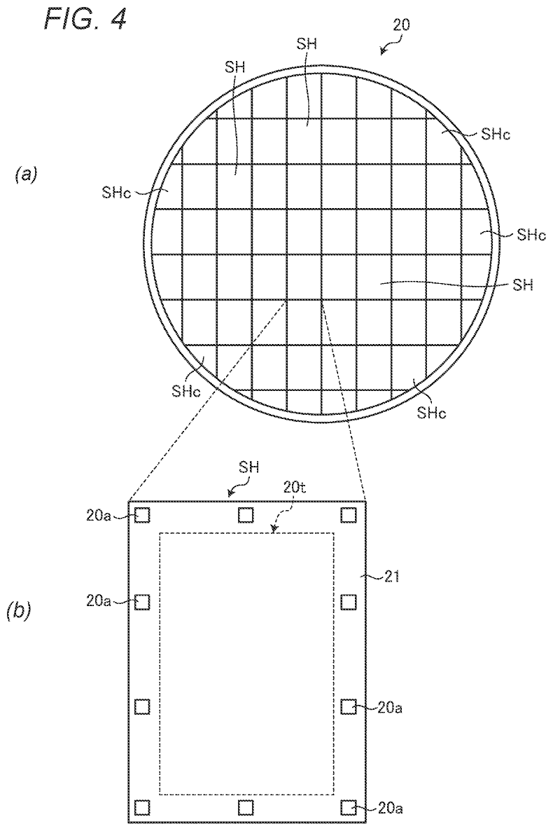

Next, a method for manufacturing a semiconductor device according to the embodiment will be described with reference to FIGS. 4, 5A to 5E, and 6A to 6C. A manufacturing step of the semiconductor device according to the embodiment includes an imprint process by the imprint apparatus 1 described above.

First, FIG. 4 illustrates an example of the wafer 20 which is a process target by the imprint apparatus 1. FIG. 4 is a schematic diagram illustrating an example of a configuration of the wafer 20 according to the embodiment. FIG. 4, part (a) is a top view of the whole wafer 20, and FIG. 4, part (b) is an enlarged top view of one shot region SH.

As illustrated in FIG. 4, an upper surface of the wafer 20 is partitioned into a plurality of shot regions SH. The full shot regions in plurality of shot regions SH each have a rectangular shape, and are arranged in a matrix configuration on the entire surface of the wafer 20. Each of the shot regions SH are regions that are individually processed in at least one step in a plurality of manufacturing steps of a semiconductor device.

That is, for example, in the imprint process, a single shot region SH corresponds to the region onto which the pattern 10p of the template 10 is transferred in one imprint process (one pressing of the template 10). Therefore, one shot region SH may have an area and a shape substantially equal to an area and a shape of an upper surface of the mesa portion 10m of the template 10, for example.

However, the plurality of shot regions SH also include what may be termed missing or partial shot regions SHc at an outer periphery (edge) of the wafer 20. The missing shot region SHc lacks a part of the predetermined configuration to be provided in the full shot region SH, though this is by design.

That is, the missing shot region SHc has a less than full area of the normal shot region SH and can be said to be a fraction of the full area or a fractional shot area. The total area and overall shape of the missing shot regions SHc may vary depending on position on the wafer 20 at which the missing shot region SHc is disposed.

FIG. 4, part (b) illustrates a full shot region SH. As illustrated in FIG. 4, part (b), each shot region SH has a transfer region 20t in which the pattern 10p of the template 10 is transferred. The transfer region 20t becomes an element region of the semiconductor device after additional steps are performed. One or a plurality of semiconductor devices can be obtained from each element region. That is, multiple devices (or dies) may be present in a single shot region SH (or transfer region 20t)

Furthermore, depending on the shape and the area of the missing shot region SHc, the missing shot region SHc may be of a type from which one or more semiconductor devices might be obtained and or a type from which no semiconductor device can be obtained. The imprint process is not usually performed on a missing shot region SHc from which no semiconductor device can be obtained.

A plurality of alignment marks 20a are provided around the transfer region 20t. These alignment marks 20a can be formed in a process-target film 21 on the upper surface of the wafer 20, a film below the process-target film 21, and/or the wafer 20. Each alignment mark 20a is used in a pair with the corresponding alignment mark 10a of the template 10 for position alignment between the wafer 20 and the template 10.

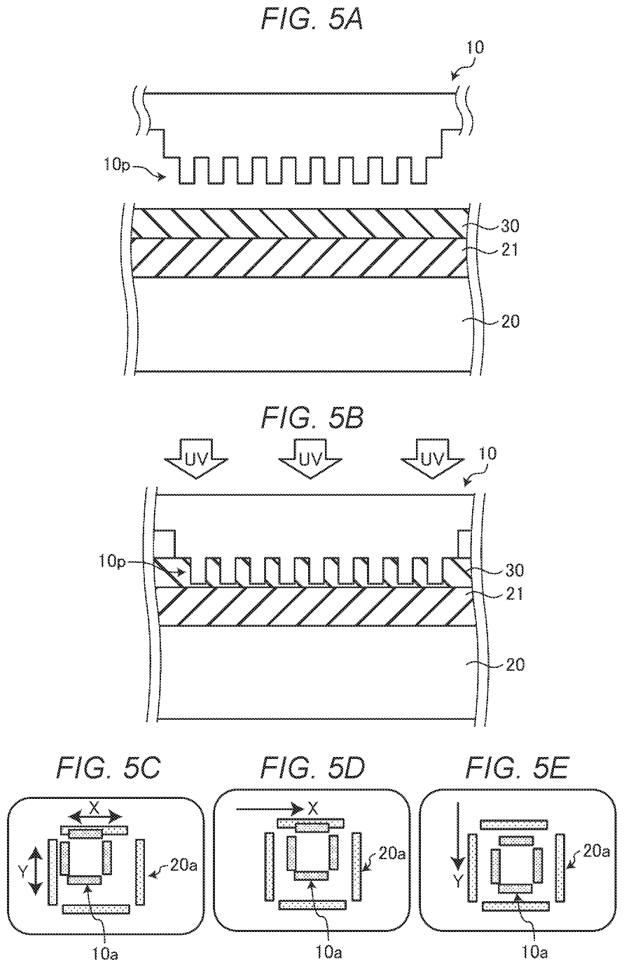

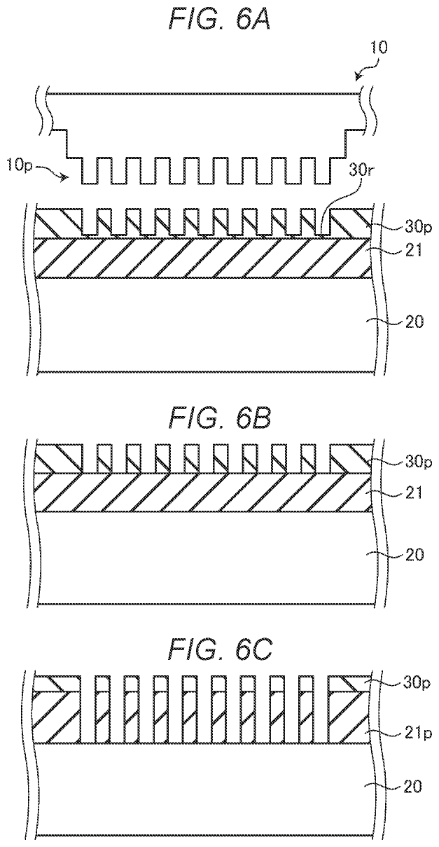

FIGS. 5A to 5E and FIGS. 6A to 6C are cross-sectional diagrams sequentially illustrating a part of a procedure of a method for manufacturing a semiconductor device according to the embodiment. The process illustrated in FIGS. 5A to 5E and FIGS. 6A to 6C is also a pattern formation method for forming a pattern based on the pattern 10p of the template 10, on the process-target film 21 formed on the wafer 20.

The process illustrated in FIGS. 5A to 6A illustrates an example of a procedure of an imprinting method by the imprint apparatus 1. The process illustrated in FIGS. 5A to 6A is also a pattern formation method for forming the pattern 10p on a resist film 30 formed on the wafer 20. In this manner, the imprint process and the pattern formation process by the imprint apparatus 1 are executed as one step in the manufacturing of the semiconductor device.

As illustrated in FIG. 5A, the process-target film 21 is formed on the wafer 20. The process-target film 21 is, for example, a silicon oxide film, a silicon nitride film, a metal film, or the like. The process-target film 21 is eventually processed into a shape corresponding to the pattern 10p of the template 10.

One or more underlying films may be under the process-target film 21, depending on stages of the manufacturing step performed on the wafer 20 up to this point. Alternatively, when the imprint process is performed for the purpose of processing the surface of the wafer 20, the process-target film 21 may be a surface layer of the wafer 20. The wafer 20 may be a silicon wafer in some examples.

The plurality of alignment marks 20a to be used for position alignment with the template 10 are formed on the process-target film 21, the underlying film, or the wafer 20, as described above.

The wafer 20 is suctioned to the wafer chuck 82b, and the wafer stage 82 is then moved to be below the liquid droplet dropping device 87. Further, the liquid droplet dropping device 87 dispenses a resist onto the process-target film 21 in the shot region SH on which the imprint process is to be next performed among the plurality of shot regions SH. The liquid droplet dropping device 87 dispenses a resist by using an ink jet method or the like.

The resist from the liquid droplet dropping device 87 is, for example, an organic material such as a photocurable resist that can be cured (hardened) by irradiation with ultraviolet rays or the like. When the resist is first dispensed from the liquid droplet dropping device 87, the resist is in an uncured liquid state.

Thus, the resist film 30 is formed on the process-target film 21 in one shot region SH.

The uncured resist film 30 formed by the ink jet method may be arranged as individual droplets in the shot region SH, regardless of depiction in FIG. 5A. In other examples, the resist film 30 may be formed by using a spin coating method or the like. In this case, the resist film 30 is formed substantially uniformly over the entire surface of the wafer 20 in the same process.

The wafer stage 82 holding the wafer 20 is moved, and the shot region SH on which the imprint process is to be performed is disposed below the template 10 being held by the template stage 81 of the imprint apparatus 1.

As illustrated in FIG. 5B, the template stage 81 is lowered to press the pattern 10p of the template 10 against the resist film 30.

At this time, the driving unit 814 provided on the template stage 81 adjusts a lowering speed and a lowering distance of the template stage 81, a levelness (tilt) of the template 10 with respect to the wafer 20, an imprinting force of the template 10, and the like.

Further, the driving unit 814 adjusts a lowered position of the template stage 81 such that a gap is left between the template 10 and the process-target film 21 of the wafer 20 to prevent direct contact between the template 10 and the process-target film 21.

When the pattern 10p is brought into contact with the resist film 30, the rear surface of the template 10 is pressed by the pressing unit 813 provided on the template stage 81, and a center portion of the pattern 10p of the template 10 is bent (bowed) toward the wafer 20. Thus, this helps prevent air bubbles from being trapped in uneven portions of the pattern 10p.

While the pattern 10p is in contact with the resist film 30, the plurality of alignment marks 10a provided on the template 10 are observed by the imaging sensor 83 of the imprint apparatus 1. The contact state between the pattern 10p and the resist film 30 is maintained until an inside of these alignment marks 10a is filled with the resist film 30. Further, during this time, recess portions of the pattern 10p of the template 10 are also filled with the resist film 30.

By filling the inside of the alignment mark 10a with the resist film 30, visibility of the alignment mark 10a and the alignment mark 20a of the wafer 20 seen through the template 10 is improved. That is, the alignment marks 10a and 20a are more easily observed by the imaging sensors 84a to 84d of the imprint apparatus 1.

Therefore, after the resist film 30 is filled, the individual alignment marks 10a of the template 10 and the individual alignment marks 20a of the wafer 20 respectively corresponding to the alignment marks 10a are observed by the imaging sensors 84a to 84d, and position alignment of the wafer 20 and the template 10 in a direction along the surface of the wafer 20 is performed. At this time, for example, while appropriately switching between the imaging sensors 84a to 84d to be used, the alignment marks 10a and 20a at positions respectively corresponding to the imaging sensors 84a to 84d can be observed and position alignment of the alignment marks 10a and 20a appropriately performed.

FIGS. 5C to 5D are different images of alignment marks 10a and 20a that may be captured by imaging sensors 84a to 84d, and illustrate a sequence in which position alignment of the wafer 20 and the template 10 can be performed by using the alignment marks 10a and 20a.

As illustrated in FIG. 5C, the alignment mark 20a of the wafer 20 has a rectangular shape configured with four bars. The alignment mark 10a of the template 10 is also configured with four bars, but has a smaller size than the alignment mark 20a.

Ideally, the relative positions of the wafer 20 and the template 10 are adjusted such that the alignment mark 10a is disposed inside the alignment mark 20a with the center positions of the alignment marks 10a and 20a coinciding with each other when observed by the imaging sensors 84a to 84d. Thus, the position alignment of the wafer 20 and the template 10 can be performed. In this state, the pattern 10p of the template 10 is transferred to the resist film 30 of the wafer 20, so that a pattern can be formed at a desired position on the wafer 20.

Further, the alignment marks 10a and 20a configured as described above are called bar-in-bar type marks and are used for precise position alignment performed after the template 10 has been brought into contact with the resist film 30 on the wafer 20. However, in other examples, the alignment marks 10a and 20a may be other types of marks such as box-in-box type marks.

Here, in the example illustrated in FIG. 5C, the alignment marks 10a and 20a have positional deviation in both the X-direction and the Y-direction.

As illustrated in FIG. 5D, the template 10 is moved in the X-direction by the driving unit 814 provided on the template stage 81 to perform position alignment of the alignment marks 10a and 20a in the X-direction.

As illustrated in FIG. 5E, the driving unit 814 moves the template 10 in the Y-direction to perform position alignment of the alignment marks 10a and 20a in the Y-direction.

Thus, position alignment of the wafer 20 and the template 10 is performed. However, in other examples, the alignment operation of the position alignment of the wafer 20 and the template 10 may be more complex than the operations illustrated in the examples in FIGS. 5C to 5E.

For example, the positions of the alignment marks 10a and 20a in the X-direction and the Y-direction may be gradually aligned while repeatedly performing fine adjustments simultaneously. Therefore, the alignment operation of the imprint apparatus 1 may be an operation of performing position alignment while sliding the template 10 on the resist film 30 on the wafer 20.

In the example described above, the template 10 is moved with respect to the wafer 20 to perform these position alignments. However, the wafer 20 may instead be moved with respect to the template 10 by the wafer stage 82 to perform the position alignment.

In the example illustrated in FIG. 5E, the position alignment of the wafer 20 and the template 10 are ideally performed, that is, a positional deviation between the wafer 20 and the template 10 reaches zero. However, in practice, the alignment operation may be ended once the amount of positional deviation becomes equal to or less than some allowable predetermined amount.

A time period for performing the alignment operation may be preset, and the alignment operation may be ended when a predetermined time is reached. Alternatively, an upper limit value for the amount of positional deviation of the alignment marks 10a and 20a in the X-direction and the Y-direction may be preset, and the alignment operation may be ended when the amount of positional deviation becomes equal to or less than the upper limit value.

Alternatively, both the alignment operation period and the alignment error threshold value are set, and the alignment operation may be ended when the alignment error becomes equal to or less than the threshold value or when the alignment operation period elapses and is timed out.

After the position alignment of the wafer 20 and the template 10 is ended, the resist film 30 is irradiated with ultraviolet rays via the template 10 while maintaining the positions of the wafer 20 and the template 10. Thus, the resist film 30 is cured in a state in which the recess portions of the pattern 10p are filled.

As illustrated in FIG. 6A, the template 10 is lifted by the driving unit 814 provided on the template stage 81. At this time, since the wafer 20 is suctioned by the wafer chuck 82b, the template 10 can be released from the wafer 20 without the wafer 20 being separated from the wafer stage 82.

Thus, a patterned resist 30p to which the pattern 10p of the template 10 is transferred is formed. A thin film called a residual resist film 30r is formed on a bottom portion of a pattern of the patterned resist 30p. This is because the template 10 is pressed against the wafer 20 in a state in which there is a gap between the template 10 and the wafer 20 to prevent a contact between the template 10 and the wafer 20, as described above.

Thus, the imprint process by the imprint apparatus 1 according to the embodiment is ended.

As illustrated in FIG. 6B, an entire surface of the patterned resist 30p is processed by, for example, oxygen plasma treatment to remove the residual resist film 30r at the pattern bottom portion. Thus, a surface of the process-target film 21 is exposed at the pattern bottom portion.

As illustrated in FIG. 6C, by performing an etching process on the process-target film 21 via the patterned resist 30p, a process-target film pattern 21p to which the patterned resist 30p is transferred to the process-target film 21 is formed.

Thereafter, by embedding a metal such as tungsten or copper in the process-target film pattern 21p, a desired structure that will be a part of the finished semiconductor device can be obtained.

For example, when the pattern 10p of the template 10 is a line-and-space pattern, the process-target film pattern 21p also has a line-and-space pattern. By embedding the metal here, wirings and the like of the semiconductor device can be obtained.

Further, when the pattern 10p of the template 10 is a dot pattern, the process-target film pattern 21p has a hole pattern in which the dot pattern is inverted. By embedding the metal here, a contact, a via, or the like of the semiconductor device can be obtained.

Thereafter, various films are further formed on the wafer 20 and a desired process is repeatedly performed on these films, so that the semiconductor device according to the embodiment is manufactured.

With imprint apparatus 1, the alignment marks 10a and 20a are used to perform position alignment of the template 10 and the wafer 20 in the X-direction and the Y-direction. Thus, when the pattern 10p of the template 10 is transferred to the resist film 30, overlapping (overlay) accuracy of the pattern 10p with respect to various structures already formed on the wafer 20 in the steps up to this point can be improved.

By improving the overlapping (positioning) accuracy of the pattern 10p, for example, if the imprint process processed for forming wirings on the process-target film 21, a contact or the like already formed in a lower layer of the process-target film 21 can be more reliably connected to the wirings of the process-target film 21.

If the imprint process for forming a contact or the like in the process-target film 21, then wirings or the like already formed in a lower layer of the process-target film 21 are more reliably connected to the contact of the process-target film 21.

### Operation Example of Imprint Apparatus

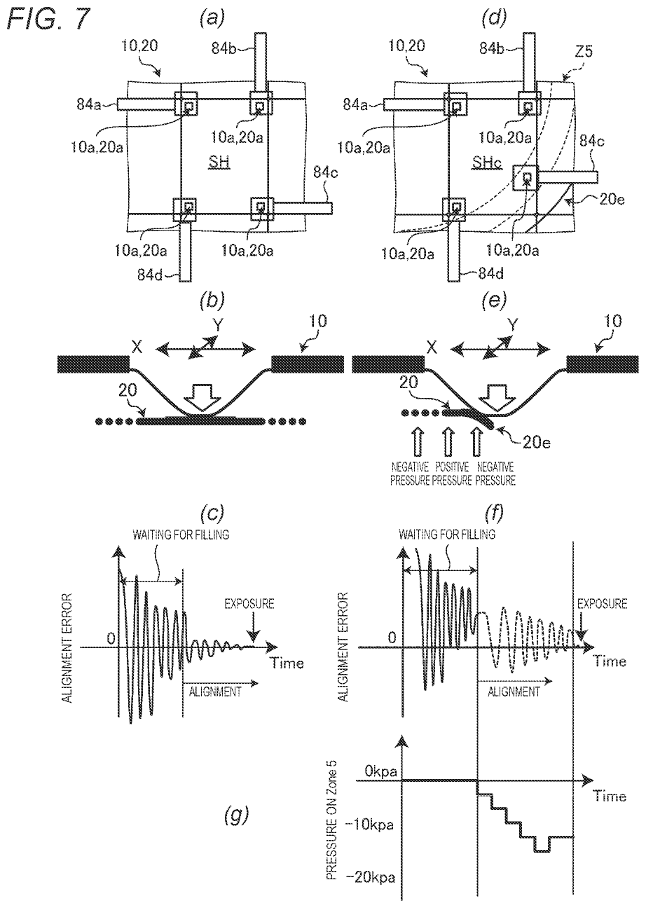

Next, an alignment operation by the imprint apparatus 1 according to the embodiment will be described with reference to FIG. 7.

FIG. 7 illustrates aspects of an example of an alignment operation performed by the imprint apparatus 1 according to the embodiment. FIG. 7, parts (a) and (d) are top views of the template 10 as viewed from above with the template 10 pressed against the resist film 30. FIG. 7, parts (b) and (e) depict the state when the template 10 is pressed against the resist film 30, as viewed from a lateral direction. FIG. 7, parts (c) and (f) are graphs illustrating aspects related to an alignment operation performed by the imprint apparatus 1 during alignment. FIG. 7, part (g) is a graph illustrating aspects of another alignment operation performed by the imprint apparatus 1 during alignment.

In performing the alignment operation, the control unit 90 of the imprint apparatus 1 presses the template 10 against the resist film 30 on the wafer 20, and causes the imaging sensor 83 to continuously image the plurality of alignment marks 10a of the template 10. Further, based on an image captured by the imaging sensor 83, the control unit 90 determines whether recess portions of the alignment marks 10a are filled with the resist film 30.

When the alignment mark 10a is filled with the resist film 30 and visibility between the alignment mark 10a and the alignment mark 20a on the wafer 20 side, which overlap with each other in the up-down direction, is improved. The control unit 90 causes the imaging sensors 84a to 84d to image these alignment marks 10a and 20a, and performs position alignment of the alignment marks 10a and 20a based on those captured images.

FIG. 7, parts (a) to (c) illustrate an example of an alignment operation performed by the imprint apparatus 1 during an imprint process on a full shot region SH.

As illustrated in FIG. 7, part (a), when performing the alignment operation, the control unit 90 causes the imaging sensors 84a to 84d to image each of the specific alignment marks 10a and 20a, among the plurality of alignment marks 10a and 20a existing in the shot region SH.

In the example in FIG. 7, part (a), the control unit 90 causes the imaging sensor 84a to image the alignment marks 10a and 20a at an upper left corner of the rectangular shot region SH, causes the imaging sensor 84b to image the alignment marks 10a and 20a at an upper right corner of the rectangular shot region SH, causes the imaging sensor 84c to image the alignment marks 10a and 20a at a lower right corner of the rectangular shot region SH, and causes the imaging sensor 84d to image the alignment marks 10a and 20a at a lower left corner of the rectangular shot region SH.

In this manner, during an alignment operation, all of the imaging sensors 84a to 84d are preferably used to image the alignment marks 10a and 20a separated from each other as much as possible among all the alignment marks 10a and 20a in the shot region SH. For example, the four corners of the shot region SH are imaged, and an alignment based on these images is performed. Thus, the amount of positional deviation can be measured over the entire shot region SH, so that it is possible to improve the overlapping accuracy of the pattern 10p of the template 10.

As illustrated in FIG. 7, part (b), when the template 10 is brought into contact with the resist film 30 (see FIG. 5B), the control unit 90 also presses the rear surface of the template 10 by using the pressing unit 813 (see FIG. 3) of the template stage 81 to bend a surface on which the pattern 10p (see FIG. 3) of the template 10 is formed toward the wafer 20 side.

Further, the control unit 90 sequentially observes the alignment marks 10a and 20a at the four corners of the shot region SH by using the imaging sensors 84a to 84d, for example, and finely adjusts positions of the template 10 in the X-direction and the Y-direction with respect to the wafer 20 by using the driving unit 814 (see FIG. 3) of the template stage 81, for example.

As illustrated in FIG. 7, part (c), an amplitude of an alignment error, which fluctuates greatly while waiting for filling of the alignment marks 10a of the template 10 with the resist film 30, is gradually decreased when alignment is started. After the alignment error becomes equal to or less than a predetermined threshold value, or after a predetermined time elapses, the control unit 90 controls the light source 89 to irradiate the resist film 30 with ultraviolet light or the like for exposure.

Further, the full shot region SH illustrated in FIG. 7, part (a) and the like is disposed closer to a center than the edge portion of the wafer 20, and the shot region SH is placed at a position overlapping with any one of the zones Z1 to Z4 of the wafer chuck 82b or across a plurality of regions of these zones Z1 to Z4.

The control unit 90 keeps the suction force constant at least in these zones Z1 to Z4, or in the zone Z5 in addition to these zones Z1 to Z4 during the alignment operation. Thus, a constant negative pressure is applied to the rear surface of the wafer 20 that overlaps with the shot region SH which is a target of the imprint process.

FIG. 7, parts (d) to (g) illustrate an example of an alignment operation performed by the imprint apparatus 1 when performing an imprint process on the missing shot region SHc.

In the example in FIG. 7, part (d), the missing shot region SHc is disposed near a wafer edge 20e at a lower right position on the surface of the wafer 20, and a missing portion of the lower right of the missing shot region SHc is placed at a position overlapping with the zone Z5 of the wafer chuck 82b.

As illustrated in FIG. 7, part (d), when the alignment operation is performed in the missing shot region SHc, the control unit 90 also causes the imaging sensors 84a to 84d to image each of the specific alignment marks 10a and 20a, among the plurality of alignment marks 10a and 20a existing in the missing shot region SHc.

In the example in FIG. 7, part (d), the control unit 90 causes the imaging sensor 84a to image the alignment marks 10a and 20a at an upper left corner of the missing shot region SHc, causes the imaging sensor 84b to image the alignment marks 10a and 20a at an upper right corner of the missing shot region SHc, and causes the imaging sensor 84d to image the alignment marks 10a and 20a at a lower left corner of the missing shot region SHc.

However, the missing shot region SHc illustrated in FIG. 7, part (d) has a missing region in the lower right portion, and the alignment marks 10a and 20a that exist at this position cannot be previously imaged. The control unit 90 causes the imaging sensor 84c, which is supposed to image the lower right portion in the full shot region SH, to image the alignment marks 10a and 20a disposed at the position overlapping with the zone Z5.

As illustrated in FIG. 7, part (e), when the template 10 is brought into contact with the resist film 30 in the imprint process for the missing shot region SHc, the control unit 90 also presses the rear surface of the template 10 by using the pressing unit 813 of the template stage 81 to bend the surface on which the pattern 10p of the template 10 is formed toward the wafer 20 side.

In addition, the control unit 90 controls the wafer chuck 82b such that a pressure for the zone Z5 becomes a negative pressure with respect to a reference pressure. The reference pressure is a pressure under an environment under which the imprint process is performed in the imprint apparatus 1, and is, for example, the atmospheric pressure. The control unit 90 sets a pressure for the zone Z4, which is a zone inside the zone Z5, at least adjacent to the zone Z5 to a positive pressure with respect to the reference pressure. Further, the control unit 90 further sets a pressure for the inner zone to a negative pressure.

Thus, the wafer 20 is in a state in which a portion of the wafer 20 overlapping with the zone of the positive pressure near the wafer edge 20e bends toward the template 10 side, and a portion of the wafer 20 overlapping with the zone Z5 of the negative pressure to the wafer edge 20e warps downward.

In this manner, by bending both the template 10 and the wafer 20, the template 10 can be pressed against the resist film 30 while maintaining the pattern 10p of the template 10 and the pattern transfer surface of the wafer 20 substantially parallel. In addition, the pattern 10p of the template 10 is easily filled with the resist film 30.

For example, the control unit 90 sequentially observes the alignment marks 10a and 20a at the position overlapping with the zone Z5 of the shot region SH and the other alignment marks 10a and 20a by using the imaging sensors 84a to 84d, and adjusts the alignment marks 10a and 20a so that the amount of positional deviation of each of the alignment marks 10a and 20a is minimized.

As illustrated in FIG. 7, part (f), the control unit 90 reduces the amplitude of the alignment error while observing the alignment marks 10a and 20a disposed at positions other than the position overlapping with the zone Z5 by using the imaging sensors 84a, 84b, and 84d. For example, the control unit 90 finely adjusts the position of the template 10 in the X-direction and the Y-direction with respect to the wafer 20 by using the driving unit 814 of the template stage 81.

After the alignment error becomes equal to or less than a predetermined threshold value, or after a predetermined time elapses, the control unit 90 controls the light source 89 to irradiate the resist film 30 with ultraviolet light or the like for exposure.

As illustrated in FIG. 7, part (g), the control unit 90 observes the alignment marks 10a and 20a at the positions overlapping with the zone Z5 by using the imaging sensor 84c in parallel with the alignment operation described above by adjusting the position of the template 10, for example, and controls the wafer chuck 82b to adjust the suction force for the zone Z5, that is, the negative pressure.

The pressure for the zone Z5 is initially adjusted to a predetermined pressure, such as 0 kpa, which is lower than the atmospheric pressure, which is the reference pressure. In parallel with the position adjustment described above of the template 10, the control unit 90 gradually reduces the pressure in the zone Z5, for example, from 0 kpa to −10 kpa, −15 kpa, and the like. At this time, the control unit 90 can drop the pressure for the zone Z5, for example, in steps of −2.5 kpa.

In this manner, as the suction force in the zone Z5 is increased by lowering the pressure, the downward warpage from the portion of the missing shot region SHc overlapping with the zone Z5 to the portion of the wafer edge 20e is increased. Along with this, the relative position relationship between the alignment marks 10a and 20a that overlap the zone Z5 is also changed. This is because a bending amount of template 10 overlaid on the wafer 20 due to pressure is not substantially changed, as compared to a warpage amount of wafer edge 20e.

The control unit 90 adjusts the pressure in the zone Z5 based on such positional changes of the alignment marks 10a and 20a to minimize the alignment error of these alignment marks 10a and 20a. It is considered that even during such an alignment operation, the alignment error of these alignment marks 10a and 20a fluctuates to be gradually decreased in amplitude, in the same manner as in FIG. 7, (f) described above.

As described above, for the missing shot region SHc, one corner or more of the four corners can be missing. Thus, one or more of the imaging sensors 84 are left unused. These one or more imaging sensors 84 that would otherwise be left unused for the missing shot region SHc are used to observe the alignment marks 10a and 20a at the position overlapping with the zone Z5, and the pressure is adjusted to minimize the alignment error, so that it is possible to compensate or correct for the warpage amount of wafer 20.

After that, after the alignment error of the alignment marks 10a and 20a other than the position overlapping with the zone Z5 becomes equal to or less than a predetermined threshold value, or after a predetermined time elapses since the alignment operation based on these alignment marks 10a and 20a is started, the resist film 30 is exposed.

When a predetermined threshold value is set for the alignment error of these alignment marks 10a and 20a, a predetermined threshold value may also be set for the alignment error of the alignment marks 10a and 20a at the position overlapping with the zone Z5.

In this case, when any of the alignment error of the alignment marks 10a and 20a other than the zone Z5 or the alignment error of the alignment marks 10a and 20a of the zone Z5 becomes equal to or less than the corresponding threshold value, it is possible to end the alignment operation, and expose the resist film 30.

Alternatively, when both of these alignment errors are equal to or less than the corresponding threshold values, the alignment operation may be ended and the resist film 30 may be exposed.

The warpage amount of wafer 20 is accounted for by the alignment operation illustrated in FIG. 7, part (g) so that both a filling property of the pattern 10p of the template 10 with the resist film 30 and overlapping accuracy of the pattern 10p in the vicinity of the region overlapping with the zone Z5 of the missing shot region SHc are satisfied.

Further, the alignment marks 10a and 20a at the position overlapping with the zone Z5 for adjusting the warpage amount of wafer 20 by adjusting the pressure in the zone Z5 also may be used for the same purpose as the alignment marks 10a and 20a at positions other than the position overlapping with the zone Z5. That is, while adjusting the warpage amount of wafer 20 by adjusting the pressure in the zone Z5 and observing the alignment marks 10a and 20a at the position overlapping with the zone Z5, the position adjustment of the template 10 and the wafer 20 in the X-direction and the Y-direction may be performed.

### Comparative Example

When an imprint process is performed by an imprint apparatus, a wafer is suctioned by a wafer chuck during the imprint process so that a template can be released (pulled off from the imprinted wafer/resin) while preventing the wafer from being separated from the wafer stage. The wafer is provided with a plurality of shot regions, and the imprint process is performed separately for each individual shot region.

Here, a release force applied to the wafer depends on a position of the shot region on the wafer and the like. Therefore, a zone-divided wafer chuck may be used so that the suction force of the wafer chuck can be controlled as appropriate for each individual shot region. Thus, the suction force of the wafer chuck can be adjusted in real time with respect to the specific shot region as a process target and according to a progress of the imprint process.

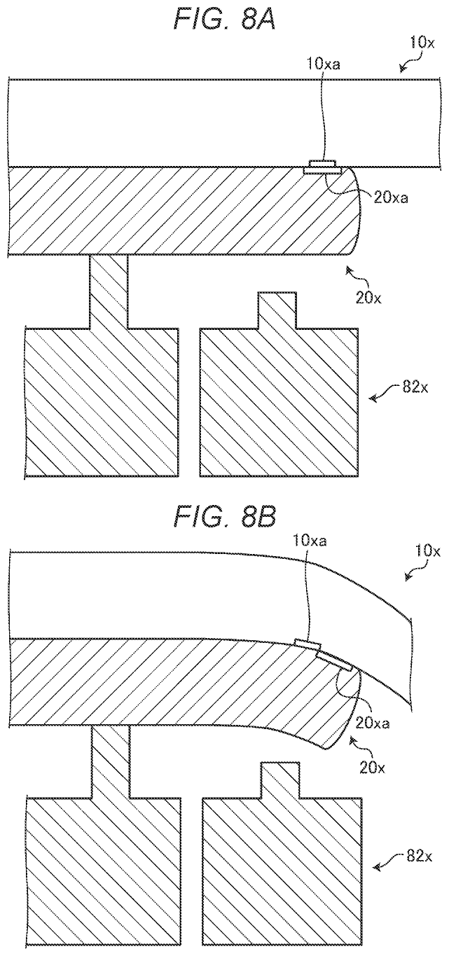

However, missing shot regions have various shapes and different sizes (areas). Since the release force applied to the wafer varies depending on the area of the shot region, if a predetermined suction force were to be uniformly applied to the missing shot region located at an edge of the wafer, a warpage amount of the wafer fluctuates (varies) for each missing shot region. Thus, overlapping accuracy of a pattern also fluctuates. FIGS. 8A and 8B illustrate a relationship between the warpage amount of wafer and the overlapping accuracy of the pattern.

FIGS. 8A and 8B are schematic diagrams illustrating a relationship between a relative position of alignment marks 10xa and 20xa of a template 10x and a wafer 20x and a warpage amount of wafer 20x of a comparative example.

As illustrated in FIGS. 8A and 8B, the wafer 20x is placed on a wafer chuck 82x. The template 10x is overlaid on the wafer 20x.

As illustrated in FIG. 8A, the template 10x is overlaid to be substantially parallel to the wafer 20x in a state in which the wafer 20x is not suctioned by the wafer chuck 82x and is not warped. In this state, positions of the alignment mark 20xa of the wafer 20x and the alignment mark 10xa of the template 10x coincide with each other in the up-down direction.

As illustrated in FIG. 8B, in a state in which the wafer chuck 82x suctions the wafer 20x and the wafer 20x is warped, the template 10x is overlaid to be substantially parallel to the wafer 20x. In this case, the alignment marks 10xa and 20xa that overlap with each other are displaced.

This is because the template 10 overlaid on the wafer 20 is hardly affected by the wafer chuck 82x while the wafer 20x is warped by being suctioned by the wafer chuck 82x.

As described above, the more the warpage of the wafer is increased, the more the overlapping accuracy of the pattern is decreased. On the other hand, if the warpage amount of wafer is too small, the filling property of the pattern of the template with the resist film is reduced. Therefore, there is an appropriate value for the warpage amount of wafer in the imprint process for the missing shot region of the wafer edge. In addition, the suction force of the wafer chuck for keeping the warpage amount of wafer at an appropriate level may differ for respective missing shot regions having different areas, as described above.

With the pattern formation method according to the embodiment, by adjusting a relative position of the template 10 and the wafer 20 in a plane direction while observing the alignment marks 10a and 20a outside the zone Z5, position alignment of these alignment marks 10a and 20a is performed. Further, by adjusting the suction force of the wafer chuck 82b for the zone Z5 while observing the alignment marks 10a and 20a in the zone Z5, and changing the warpage amount of wafer edge 20e, the position alignment of these alignment marks 10a and 20a can be performed.

Thus, instead of performing the imprint process on the missing shot region SHc disposed at the wafer edge 20e by uniformly applying a negative pressure to the wafer chuck 82b, it is possible to correct or compensate for the warpage amount of wafer 20 in real time for each individual missing shot region SHc. Therefore, the overlapping accuracy of the pattern 10p of the template 10 with respect to the wafer 20 can be improved.

With the pattern formation method according to the embodiment, the position alignment of the alignment marks 10a and 20a outside the zone Z5 and the position alignment of the alignment marks 10a and 20a inside the zone Z5 are performed in parallel. Thus, the position alignment of the template 10 and the wafer 20 in the plane direction can be efficiently performed, and the warpage amount of wafer 20 can be efficiently corrected.

With the pattern formation method according to the embodiment, the position alignment of the alignment marks 10a and 20a of the zone Z5 is performed while gradually increasing the suction force for the zone Z5 of the wafer chuck 82b. In this manner, since the warpage amount of wafer 20 is adjusted in a direction of increasing a suction force with high responsiveness, the position alignment of the alignment marks 10a and 20a in the zone Z5 can be performed quickly.

With the pattern formation method according to the embodiment, after the recess portions of the alignment marks 10a used for position alignment with the alignment marks 20a of the zone Z5 are filled with the resist film 30, the position alignment of the alignment marks 10a and 20a is started. Thus, it is possible to perform the position alignment of the alignment marks 10a and 20a with improved visibility.

With the imprint apparatus 1 according to the embodiment, by adjusting a relative position of the template 10 and the wafer 20 in the plane direction based on an image obtained by causing some of the imaging sensors 84a to 84d to image the alignment marks 10a and 20a outside the zone Z5, the position alignment of the alignment marks 10a and 20a are performed. Further, by adjusting the suction force of the wafer chuck 82b for the zone Z5 to change the warpage amount of wafer edge 20e based on an image obtained by causing the otherwise unused imaging sensor 84 to image the alignment marks 10a and 20a in the zone Z5 among the imaging sensors 84a to 84d, the position alignment of these alignment marks 10a and 20a is performed.

Thus, when performing the imprint process on the missing shot region, the warpage amount of wafer edge 20e can be corrected or compensated for by using the imaging sensor 84 that is left unused in the imprint process of the comparative example. Therefore, without adding any further components or configuration to the imprint apparatus 1, it is possible to correct or compensate for the warpage amount of wafer 20 in real time for each individual missing shot region SHc, and to improve the overlapping accuracy of the pattern 10p of the template 10 on the wafer 20.

### Modification Example

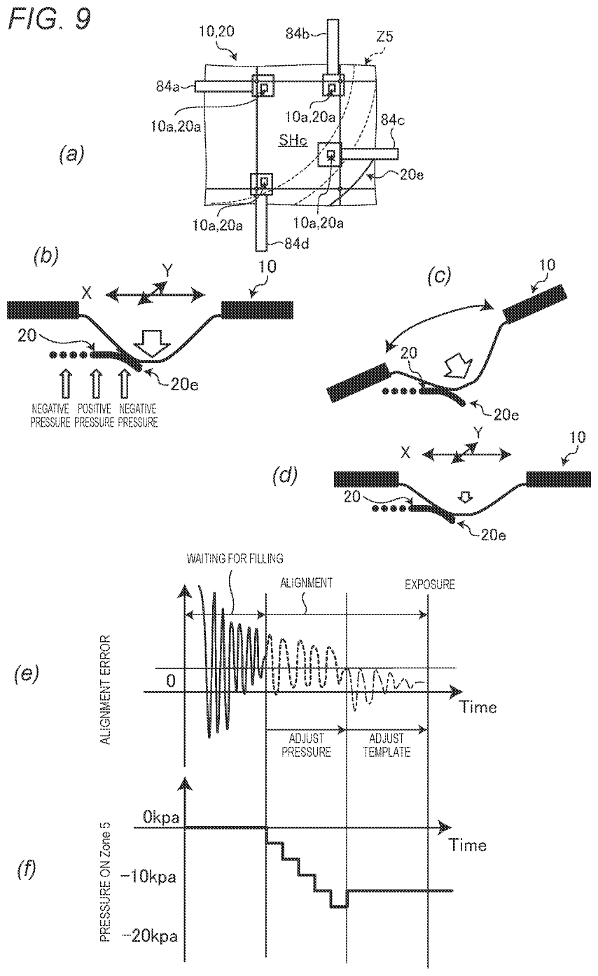

Next, a configuration of a modification example of the embodiment will be described with reference to FIG. 9. An imprint apparatus according to the modification example differs from the embodiment described above in that an inclination of the template 10 and the like can be adjusted while observing the alignment marks 10a and 20a in the zone Z5.

FIG. 9, parts (a) to (f) illustrate an example of an alignment operation performed by the imprint apparatus according to the modification example of the embodiment. FIG. 9, part (a) is a top view of the template 10 with the template 10 pressed against the resist film 30. FIG. 9, parts (b) to (d) depict the template 10 pressed against the resist film 30, as viewed from a lateral direction. FIG. 9, part (e) is a graph illustrating an alignment operation performed by the imprint apparatus 1 during alignment. FIG. 9, part (f) is a graph illustrating another alignment operation performed by the imprint apparatus 1 during alignment.

As illustrated in FIG. 9, part (a), in the same manner as the example in FIG. 7, part (d), in the missing shot region SHc of which a lower right portion is missing, the imaging sensors 84a, 84b, and 84d are used for observing the alignment marks 10a and 20a at positions deviated from positions overlapping with the zone Z5. In addition, the otherwise unused imaging sensor 84c is used for observing the alignment marks 10a and 20a at the positions overlapping with the zone Z5.

As illustrated in FIG. 9, part (b), while observing the alignment marks 10a and 20a outside the zone Z5, the driving unit 814 of the template stage 81 adjusts positions of the template 10 and the wafer 20 in the X-direction and the Y-direction. In addition, while observing the alignment marks 10a and 20a in the zone Z5, the wafer chuck 82b changes a suction force on the rear surface of the wafer 20 to adjust the warpage amount of wafer 20.

A first half of the alignment operation labeled “pressure adjustment” in FIG. 9, part (e) and a first half of a pressure change in the zone Z5 in FIG. 9, part (f), which is overlapped with a period of the “pressure adjustment”, correspond to an execution period of a process in FIG. 9, part (b) described above.

Here, in the alignment operation of the modification example, a period of an alignment operation of the alignment marks 10a and 20a in the zone Z5 can be set shorter than a period of an alignment operation of the alignment marks 10a and 20a outside the zone Z5. The alignment operation for the zone Z5 can be set to be timed out earlier than the alignment operation outside the zone Z5.

After that, if an alignment error of the alignment marks 10a and 20a in the zone Z5 does not become equal to or less than a predetermined threshold value and the time-out occurs, the control unit 90 adjusts at least one of the inclination, the imprinting force, and the bending amount toward the wafer 20 side of the template 10 while observing the alignment marks 10a and 20a in the zone Z5 by using the template stage 81 to perform position alignment of the alignment marks 10a and 20a.

During the imprint process for the missing shot region SHc disposed on the wafer edge 20e, the inclination, the imprinting force, and the bending amount toward the wafer 20 side of the template 10, all of which are described above, affect the filling property of the pattern 10p of the template 10 with the resist film 30 and the warpage amount of wafer edge 20e. This is because a balance of a force applied to each portion of the missing shot region SHc when the template 10 is pressed is changed, depending on the inclination, the imprinting force, and the bending amount toward the wafer 20 side of the template 10.

More specifically, for example, when the template 10 is tilted with respect to the wafer 20, a force applied to the wafer 20 on a side of the template 10 tilted toward the wafer 20 is stronger, and the warpage amount of wafer 20 may differ.

The imprinting force of the template 10 is a force with which the four corners of the template 10 are pressed against the wafer 20 as described above. Therefore, by increasing the imprinting force of the template 10, the force applied to an outer peripheral side becomes stronger than, for example, a center portion in the missing shot region SHc. If this portion is close to the wafer edge 20e, the warpage amount of wafer 20 can be increased. Conversely, by reducing the imprinting force of the template 10, for example, the force applied to the outer peripheral side is reduced than a force applied to the center portion of the missing shot region SHc, and the warpage amount of wafer 20 can be reduced.

In addition, if the pressure applied to the rear surface of the template 10 is low, the bending amount of template 10 toward the wafer 20 side becomes smaller. For example, the force is applied more uniformly over the entire surface of the missing shot region SHc, and the warpage amount of wafer 20 can be reduced. Conversely, if the pressure applied to the rear surface of the template 10 is high, the bending amount of template 10 toward the wafer 20 side is increased, and if this portion is close to the wafer edge 20e, the warpage amount of wafer 20 can become larger.

Therefore, by controlling the inclination, the imprinting force, and the bending amount toward the wafer 20 side of the template 10, the warpage amount of wafer edge 20e can be adjusted to perform position alignment of the alignment marks 10a and 20a in the zone Z5. A specific example is illustrated in FIG. 9, part (c) and (d).

As illustrated in FIG. 9, part (c), after the adjustment of the warpage amount of wafer 20 by controlling the suction force of the wafer chuck 82b is timed out, the control unit 90 continues to observe the alignment marks 10a and 20a in the zone Z5, for example, and adjusts the inclination of the template 10 with respect to the wafer 20 by controlling the driving unit 814 of the template stage 81.

As illustrated in FIG. 9, part (d), after the adjustment of the warpage amount of wafer 20 by controlling the suction force of the wafer chuck 82b is timed out, the control unit 90 can continue to observe the alignment marks 10a and 20a in the zone Z5, for example, and adjust the imprinting force of the template 10 by controlling the driving unit 814 of the template stage 81.

Further, the control unit 90 can continue to observe the alignment marks 10a and 20a in the zone Z5, for example, and change the pressure on the rear surface of the template 10 and adjust the bending amount of template 10 to the wafer 20 side by controlling the pressing unit 813 of the template stage 81.

As illustrated in FIG. 9, part (e), even after the pressure adjustment period of the zone Z5 at least one of the inclination, the imprinting force, and the bending amount toward the wafer 20 side of the template 10 can be continually adjusted by using the alignment marks 10a and 20a in the zone Z5 in parallel with the position alignment of the template 10 and the wafer 20 in the plane direction by using the alignment marks 10a and 20a outside the zone Z5, so that the amplitude of the alignment error can be further reduced and the pattern 10p of the template 10 can be transferred to the resist film 30 with appropriate overlapping accuracy.

As illustrated in FIG. 9, part (f), after the pressure adjustment period of the zone Z5, during the adjustment of the inclination, the imprinting force, and the bending amount toward the wafer 20 side of the template 10, the suction force for the zone Z5 is maintained to be an appropriate value obtained at a time when the pressure adjustment period of the zone Z5 is timed out.

Further, among the inclination, the imprinting force, and the bending amount toward the wafer 20 side of the template 10, the warpage amount of wafer 20 is more significantly affected by the inclination of the template 10 next to the adjustment of the suction force in the zone Z5. In addition, the imprinting force and the bending amount of template 10 have similar (opposite direction) effects in terms of changing the balance of the forces applied to the center portion and the outer peripheral portion of the missing shot region SHc.

Therefore, after the pressure adjustment period of the zone Z5 is timed out, for example, adjustment of the inclination of the template 10 can be preferentially performed among the inclination, the imprinting force, and the bending amount toward the wafer 20 side of the template 10.

In this case, when the alignment error of the alignment marks 10a and 20a in the zone Z5 does not fall below a value equal to or less than a predetermined threshold value and the time-out occurs again, either adjustment of the imprinting force of the template 10 or adjustment of the bending amount toward the wafer 20 side may be performed. After that, when the alignment error of the alignment marks 10a and 20a in the zone Z5 becomes equal to or less than the predetermined threshold value, or when the alignment operation of the alignment marks 10a and 20a outside the zone Z5 is timed out, the adjustment of the imprinting force or the bending amount of template 10 may be ended.

In addition, when adjusting at least one of the pressure for the zone Z5, the inclination, the imprinting force, and the bending amount of the template 10, the alignment marks 10a and 20a in the zone Z5 may be used for position alignment of the template 10 and the wafer 20 in the plane direction, in the same manner as the other alignment marks 10a and 20a outside the zone Z5.

With the pattern formation method according to the modification example, the relative position between the template 10 and the wafer 20 is adjusted and the suction force of the wafer chuck 82b for the zone Z5 is adjusted, and at least one of the inclination of the template 10, the pressing force against the pattern 10p, and the bending of the pattern 10p with rear pressure adjustment of the template 10 can be adjusted to perform position alignment of the alignment mark of the zone Z5. Thus, it is possible to further improve the overlapping accuracy of the pattern 10p of the template 10 with respect to the wafer 20.

With the pattern formation method according to the modification example, after position alignment of the alignment marks 10a and 20a in the zone Z5 is performed in parallel with position alignment of the alignment marks 10a and 20a outside the zone Z5, if a position alignment state of the alignment marks 10a and 20a of the zone Z5 does not satisfy a predetermined condition at least one of the inclination of the template 10, the pressing force for the pattern 10p, and the bending of the pattern 10p can be adjusted in parallel with the position alignment of the alignment marks 10a and 20a outside the zone Z5 to perform the position alignment of the alignment marks 10a and 20a inside the zone Z5.

In this manner, after performing pressure adjustment of the wafer chuck 82b, which is more effective for adjusting the warpage amount of wafer 20, when a predetermined alignment condition is not satisfied, one of the inclination of the template 10, the pressing force for the pattern 10p, and the bending of the pattern 10p can be adjusted, so that it is possible to efficiently and more precisely perform the position alignment of the alignment marks 10a and 20a.

With the pattern formation method according to the modification example, the same effect as the pattern formation method according to the embodiment described above can be obtained.

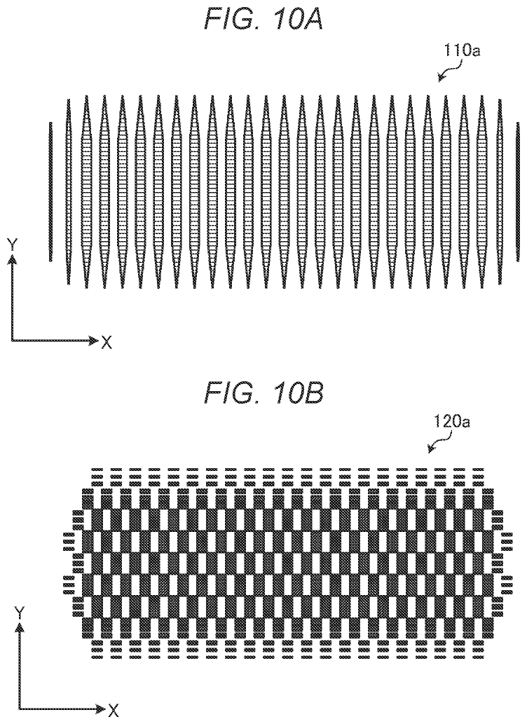

In the embodiment and modification example, bar-in-bar type marks are used as the alignment marks 10a and 20a. However, the alignment marks provided on the template 10 and the wafer 20 may be a type other than bar-in-bar type marks. FIGS. 10A and 10B illustrate a moiré mark as an example of another mark.

FIGS. 10A and 10B are top views illustrating an example of a configuration of moiré-type alignment marks 110a and 120a provided on a template and a wafer according to another modification example of the embodiment.

As illustrated in FIG. 10A, on the template side, the alignment mark 110a having a one-dimensional periodic structure in which a plurality of lines and spaces extending in a direction along the Y-direction are arranged at regular intervals in the X-direction is provided.

The alignment marks 120a having a two-dimensional periodic structure in a checkered lattice shape (check pattern) in which the alignment marks 120a are arranged at regular intervals in the X-direction and the Y-direction is provided on the wafer side of the other modification example. A period of the structure of the alignment mark 120a in the X-direction is slightly different from a period of the alignment mark 110a in the X-direction.

With such a configuration, when the alignment marks 110a and 120a are overlapped with each other in the up-down direction, interference fringes called moiré patterns or fringes are generated. Further, when a relative position of the template and the wafer in the other modification example is moved in the X-direction in a state in which the alignment marks 110a and 120a are overlapped with each other, the interference fringes are moved in the X-direction.

By detecting such movement of the interference fringes as a signal waveform in an image captured by the imaging sensor 84, it is possible to calculate the amount of positional deviation between the template and the wafer in the X-direction.

In order to measure the amount of positional deviation between the template and the wafer in the Y-direction, the alignment marks 110a and 120a in FIGS. 10A and 10B may be rotated together by 90 degrees and disposed at the template and the wafer. Thus, the alignment marks 110a and 120a have slightly different periods in the Y-direction.

When these alignment marks 110a and 120a are overlapped with each other in the up-down direction and the relative position of the template and the wafer is moved in the Y-direction, the interference fringes are moved in the Y-direction.

By detecting such movement of the interference fringes as a signal waveform in the image captured by the imaging sensor 84, it is possible to calculate the amount of positional deviation between the template and the wafer in the Y-direction.

By detecting and analyzing the interference fringes in the moiré-type alignment marks 110a and 120a as electrical signals, the amount of positional deviation between the template and the wafer can be quantified with greater accuracy, and position alignment of the template and the wafer can be performed with high precision.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A pattern formation method, comprising:
holding a substrate using a suction chuck, the substrate having a plurality of shot regions thereon and the suction chuck having a first suction region for suctioning an outer edge portion of the substrate and a second suction region for suctioning an inner region of the substrate;
forming a resin film on a shot region of the plurality of shot regions; and
pressing a template against the resin film on the shot region to transfer a pattern of the template to the resin film, wherein
the plurality of shot regions include:
a partial shot region in the outer edge portion and the inner region of the substrate, the partial shot region having a first alignment mark in the inner region and a second alignment mark in the outer edge portion,
the template includes:
a third alignment mark for position alignment with the first alignment mark, and
a fourth alignment mark for position alignment with the second alignment mark,
the position alignment of the first and third alignment marks is performed with the template being pressed against the resin film in the partial shot region, and
the position alignment of the second and fourth alignment marks is performed by adjusting a suction force for the first suction region for changing a warpage amount of the outer edge portion while observing the second and fourth alignment marks through the template with the template being pressed against the resin film in the partial shot region.

2. The pattern formation method according to claim 1, wherein the position alignment of the second and fourth alignment marks is performed while gradually increasing the suction force for the first suction region.

3. The pattern formation method according to claim 1, wherein the position alignment of the second and fourth alignment marks is performed by adjusting a tilt of the template, a pressing force of the template, and a bowing of the template.

4. The pattern formation method according to claim 1, wherein the position alignment of the second and fourth alignment marks is performed by adjusting a pressing force of the template.

5. The pattern formation method according to claim 1, wherein the position alignment of the second and fourth alignment marks is performed by adjusting a bowing of the template.

6. The pattern formation method according to claim 1, wherein
the second and fourth alignment marks are moiré-type marks, and
the first and third alignment marks are moiré-type marks.

7. A semiconductor device manufacturing method, comprising:
holding a substrate using a suction chuck, the substrate having a plurality of shot regions thereon and the suction chuck having a first suction region for suctioning an outer edge portion of the substrate and a second suction region for suctioning an inner region of the substrate;
forming a resin film on a shot region of the plurality of shot regions;
pressing a template against the resin film on the shot region to transfer a pattern of the template to the resin film;
curing the patterned resin film on the substrate; and
processing a process film on the substrate using the cured resin film to transfer a pattern to the process film, wherein
the plurality of shot regions include:
a partial shot region in the outer edge portion and the inner region of the substrate, the partial shot region having a first alignment mark in the inner region and a second alignment mark in the outer edge portion,
the template includes:
a third alignment mark for position alignment with the first alignment mark, and
a fourth alignment mark for position alignment with the second alignment mark,
the position alignment of the first and third alignment marks is performed with the template being pressed against the resin film in the partial shot region, and
the position alignment of the second and fourth alignment marks is performed by adjusting a suction force for the first suction region for changing a warpage amount of the outer edge portion while observing the second and fourth alignment marks through the template with the template being pressed against the resin film in the partial shot region.

8. The semiconductor device manufacturing method according to claim 7, wherein the position alignment of the second and fourth alignment marks is performed while gradually increasing the suction force for the first suction region.

9. The semiconductor device manufacturing method according to claim 7, wherein the position alignment of the second and fourth alignment marks is performed by adjusting a tilt of the template, a pressing force of the template, and a bowing of the template.

10. The semiconductor device manufacturing method according to claim 7, wherein the position alignment of the second and fourth alignment marks is performed by adjusting a pressing force of the template.

11. The semiconductor device manufacturing method according to claim 7, wherein the position alignment of the second and fourth alignment marks is performed by adjusting a bowing of the template.

12. The semiconductor device manufacturing method according to claim 7, wherein the process film is a metal film.

13. The semiconductor device manufacturing method according to claim 7, wherein the resin film is cured by ultraviolet light.

14. The semiconductor device manufacturing method according to claim 7, wherein
the second and fourth alignment marks are moiré-type marks, and
the first and third alignment marks are moiré-type marks.

15. An imprint apparatus, comprising:
a suction chuck having a first suction region for suctioning an outer edge portion of a substrate and a second suction region for suctioning an inner region of the substrate;
a template stage configured to hold a template, adjust a relative position of the substrate and the template in a plane direction, and move up and down with respect to the substrate;
a first imaging sensor that image the substrate through the template;
a second imaging sensor that images the substrate through the template; and
a control unit configured to control the suction chuck, the template stage, and the first and second imaging sensors, wherein
the substrate has a plurality of shot regions including a partial shot region in the outer edge portion and the inner region of the substrate, the partial shot region including a first alignment mark in the inner region, a second alignment mark in the outer edge portion,
the template has a third alignment mark for position alignment with the first alignment mark, and a fourth alignment mark for position alignment with the second alignment mark, and
the control unit is configured to:
cause the suction chuck to suction the outer edge portion and the inner region of the substrate,
perform the position alignment of the first and third alignment marks based on images of the first and third alignment marks from the first imaging sensor through the template while the template is pressed against a resin film in the partial shot region, and
perform the position alignment of the second and fourth alignment marks by adjusting a suction force for the first suction region for changing a warpage amount of the outer edge portion based on images of the second and fourth alignment marks from the second imaging sensor through the template while the template is pressed against the resin film in the partial shot region.

16. The imprint apparatus according to claim 15, wherein the control unit is configured to perform the position alignment of the second and fourth alignment marks while gradually increasing the suction force for the first suction region.

17. The imprint apparatus according to claim 15, wherein the control unit is configured to perform the position alignment of the second and fourth alignment marks by adjusting a tilt of the template, a pressing force of the template, or a bowing of the template.

18. The imprint apparatus according to claim 15, wherein the control unit is configured to perform the position alignment of the second and fourth alignment marks by adjusting a pressing force of the template.

19. The imprint apparatus according to claim 15, wherein the control unit is configured to perform the position alignment of the second and fourth alignment marks by adjusting a bowing of the template.

20. The imprint apparatus according to claim 15, wherein the control unit is configured to perform the position alignment of the second and fourth alignment marks by adjusting a tilt of the template.
